(19) United States
(12) Patent Application Publication
(10) Pub. No.: US 2025/0157889 A1
(43) Pub. Date: May 15, 2025

(54) Forming Multiple TSVs with Different Formation Schemes

(71) Applicant: Taiwan Semiconductor Manufacturing Co., Ltd., Hsinchu (TW)

(72) Inventors: Chih-Chieh Chang, Hsinchu (TW); Chih Hsin Yang, Zhubei City (TW); Mao-Nan Wang, Kaohsiung City (TW); Kuan-Hsun Wang, Hsinchu (TW); Yang-Hsin Shih, Hsinchu (TW); Yun-Sheng Li, Hsinchu (TW); Liang-Wei Wang, Hsinchu (TW); Dian-Hau Chen, Hsinchu (TW)

(21) Appl. No.: 18/582,326

(22) Filed: Feb. 20, 2024

Related U.S. Application Data
(60) Provisional application No. 63/598,616, filed on Nov. 14, 2023.

(51) Int. Cl. H01L 23/48; H01L 21/768; H01L 23/00; H01L 23/31

(52) U.S. Cl. CPC H01L 23/481; H01L 21/76831; H01L 21/76877; H01L 21/76898; H01L 23/3107; H01L 24/08; H01L 24/80; H01L 2224/08145; H01L 2224/80895; H01L 2924/181

(57) ABSTRACT

A method includes forming a first device die comprising forming an integrated circuit on a semiconductor substrate; and forming an interconnect structure on the semiconductor substrate. The interconnect structure has a plurality of metal layers. The method further includes bonding a second device die to the first device die, and forming gap-fill regions surrounding the second device die. In a first formation process, a first TSV is formed to penetrate through the semiconductor substrate, wherein the first TSV has a first width. In a second formation process, a second TSV is formed to penetrate through the semiconductor substrate. The second TSV has a second width different from the first width.

### PRIORITY CLAIM AND CROSS-REFERENCE

This application claims the benefit of the following provisionally filed U.S. Patent application: Application No. 63/598,616, filed on Nov. 14, 2023, and entitled “NOVEL AND ALL-IN-ONE TSV MULTI-CD FLOW FOR HIGH PPA,” which application is hereby incorporated herein by reference.

### BACKGROUND

Through-Silicon Vias (TSVs) are used as parts of the electrical paths in device dies, so that the conductive features on opposite sides of the device dies may be interconnected. The formation process of a TSV may include etching a semiconductor substrate to form an opening, filling the opening with a conductive material to form the TSV, performing a backside grinding process to remove a portion of the semiconductor substrate from backside and to expose the TSV, and forming an electrical connector on the backside of the semiconductor substrate to connect to the TSV.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-15 illustrate the cross-sectional views of intermediate stages in the formation of a package and through-silicon vias in accordance with some embodiments.

FIGS. 16-31 illustrate the cross-sectional views of intermediate stages in the formation of a package and through-silicon vias in accordance with some embodiments.

FIGS. 32-34 illustrate the cross-sectional views of intermediate stages in the formation of a package and through-silicon vias in accordance with some embodiments.

FIGS. 35-37 illustrate the cross-sectional views of intermediate stages in the formation of a package and through-silicon vias in accordance with some embodiments.

FIGS. 38-41 illustrate the cross-sectional views of packages including through-silicon vias in accordance with some embodiments.

FIG. 42 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Packages and the methods of forming the same are provided. In accordance with some embodiments of the present disclosure, a device die is formed, with a plurality of through-silicon vias (TSVs, also referred to as through-vias, through-substrate vias or through-semiconductor vias) being formed to penetrate through the semiconductor substrate of the device die. The plurality of TSVs may be formed using different processes such as a TSV-first process, a TSV-middle process, a TSV-last process, or the like. Also, the plurality of TSVs may have different landing levels. By adjusting the formation processes, the TSVs in the device die may have different widths (lateral sizes) to satisfy the customized requirements of conducting power and signals, while maintaining the occupied chip areas occupied by the TSVs as small as possible.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

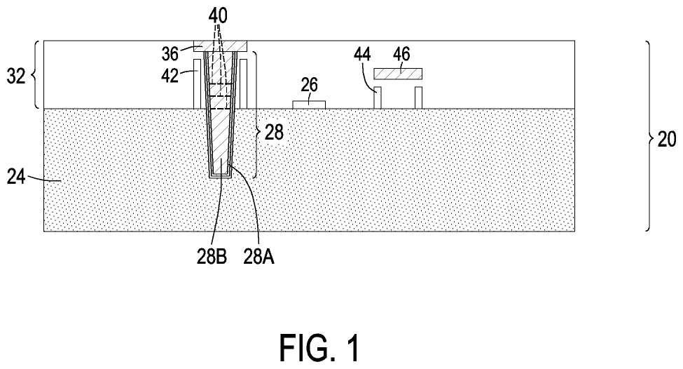

FIGS. 1 through 15 illustrate the cross-sectional views of intermediate stages in the formation of a package in accordance with some embodiments of the present disclosure. The process includes the formation of first TSVs through a TSV-first process and second TSVs formed through a TSV-last process. The package may also involve face-to-back bonding.

Referring to FIG. 1, package component 20 is formed. In accordance with some embodiments, package component 20 is a device die, which is sawed from a device wafer. In accordance with alternative embodiments, package component 20 is an interposer die, which is free from active devices, and may or may not include passive devices. In accordance with yet alternative embodiments, package component 20 is or comprises a package such as an Integrated Fan-Out (InFO) Package, a redistribution structure including redistribution lines therein, or the like. Accordingly, package component 20 may also be referred to a device die 20 hereinafter, while it may also be of other types.

In accordance with some embodiments, package component 20 includes semiconductor substrate 24 and the features formed at a top surface of semiconductor substrate 24. Semiconductor substrate 24 may be formed of or comprise crystalline silicon, crystalline germanium, crystalline silicon germanium, carbon-doped silicon, a III-V compound semiconductor, or the like. Semiconductor substrate 24 may also be a bulk semiconductor substrate or a Semiconductor-On-Insulator (SOI) substrate.

In accordance with some embodiments, package component 20 may or may not include integrated circuit devices 26, which are formed at the front surface (the illustrated top surface) of semiconductor substrate 24. Integrated circuit devices 26 may include Complementary Metal-Oxide Semiconductor (CMOS) transistors, resistors, capacitors, diodes, and/or the like in accordance with some embodiments. The details of integrated circuit devices 26 are not illustrated herein.

In accordance with some embodiments, package component 20 includes TSVs 28 (with one TSV 28 illustrated as an example). TSVs 28 may be electrically connected to the integrated circuit devices 26. In accordance with some embodiments, TSVs 28 extend from the top surface (the illustrated top surface in FIG. 1) of semiconductor substrate 24 to an intermediate level of semiconductor substrate 24. The intermediate level of semiconductor substrate 24 is between the top surface and the bottom surface of semiconductor substrate 24.

Each of the TSVs 28 may include a TSV liner 28A and a metallic material 28B. The TSV liner 28A may include a dielectric isolation layer (such as a SiN layer, a SiO layer, or the like), and a conductive diffusion barrier layer (such as a TiN layer). The metallic material 28B may include copper, tungsten, cobalt, or the like.

Interconnect structure 32 is formed over semiconductor substrate 24 and integrated circuit devices 26. Interconnect structure 32 may include an Inter-Layer Dielectric (ILD, not marked separately) filling the spaces between the gate stacks of transistors (not shown) in integrated circuit devices 26. In accordance with some embodiments, the ILD is formed of silicon oxide, Phospho Silicate Glass (PSG), Boro Silicate Glass (BSG), Boron-doped Phospho Silicate Glass (BPSG), Fluorine-doped Silicate Glass (FSG), or the like. The ILD may be formed using spin-on coating, Flowable Chemical Vapor Deposition (FCVD), or the like. In accordance with some embodiments of the present disclosure, the ILD may also be formed using a deposition method such as Plasma Enhanced Chemical Vapor Deposition (PECVD), Low Pressure Chemical Vapor Deposition (LPCVD), or the like.

Contact plugs (not shown) are formed in the ILD, and are used to electrically connect integrated circuit devices 26 to overlying metal lines and vias. In accordance with some embodiments of the present disclosure, the contact plugs are formed of or comprise a conductive material selected from tungsten, aluminum, copper, titanium, tantalum, titanium nitride, tantalum nitride, alloys therefore, and/or multi-layers thereof. The formation of the contact plugs may include forming contact openings in the ILD, filling a conductive material(s) into the contact openings, and performing a planarization process (such as a Chemical Mechanical Polish (CMP) process or a mechanical grinding process) to level the top surfaces of the contact plugs with the top surface of the ILD.

In accordance with some embodiments, interconnect structure 32 further includes a plurality of dielectric layers over the ILD, and a plurality of conductive features such as metal lines/pads and vias in the dielectric layers. The dielectric layers may include low-k dielectric layers (also referred to as Inter-metal Dielectrics (IMDs)) in accordance with some embodiments. The dielectric constants (k values) of the low-k dielectric layers may be lower than about 3.5 or 3.0, for example. The low-k dielectric layers may comprise a carbon-containing low-k dielectric material, Hydrogen SilsesQuioxane (HSQ), MethylSilsesQuioxane (MSQ), or the like.

The formation of the metal lines and vias in the interconnect structure 32 may include single damascene processes and/or dual damascene processes. Accordingly, the metal lines and vias may include copper, and may also include diffusion barriers formed of TiN, Ti, TaN, Ta, or the like.

In accordance with some embodiments, the interconnect structure 32 includes top conductive (metal) features 36 such as metal lines, metal pads, or vias in a top dielectric layer (denoted as dielectric layer), which is the top layer of the dielectric layers in the interconnect structure 32. In accordance with some embodiments, the TSVs 28 extend to the top metal features 36, which may be in the top metal layer. The TSVs 28 may physically contact top metal features 36, or may be connected to the top metal features 36 through vias (not shown). The top metal features 36 in the top dielectric layer may also be formed of copper or a copper alloy, and may have a dual damascene structure or a single damascene structure.

In accordance with some embodiments, the TSVs 28 are formed through a TSV-middle process, in which TSVs are formed after the majority of the interconnect structure 32 has been formed. For example, the TSVs may be formed after a metal layer immediately below the top metal layer has been formed, and before the formation of top metal features 36. The formation process may include etching the dielectric layers in the interconnect structure 32 to form TSV openings, depositing a conformal dielectric liner, depositing barrier seed layer(s), and filling the remaining TSV openings with a metallic material. A planarization process such as a CMP process is then performed to remove excess materials and forming TSVs 28. The top conductive features (metal pads) 36 are then formed, for example, in a damascene process.

In accordance with alternative embodiments, the TSVs 28 may be formed in a TSV-first process, which may be formed before the formation of the interconnect structure 32, or after the formation of the contact plugs and the ILD of the interconnect structure 32, but before the formation of other metal layers in the interconnect structure 32. FIG. 1 illustrates the possible levels 40 of when the TSVs 28 are formed using the TSV-first process.

In accordance with yet alternative embodiments, some TSVs 28 are formed using the TSV-middle process, while some other TSVs 28 are formed using the TSV-first process. As will be discussed in subsequent processes, the TSVs formed using TSV-middle process are taller than (and may be wider than) the TSVs formed using the TSV-first process.

Interconnect structure 32 may also include a passivation layer (not shown), which covers the top metal features 36. The passivation layer may be formed of a non-low-k dielectric material, which may comprise silicon and another element(s) including oxygen, nitrogen, carbon, and/or the like. For example, the passivation layer may be formed of or comprises SiON, SiN, SiOCN, SiCN, SiOC, SiC, or the like.

In accordance with some embodiments, each of the TSVs 28 is surrounded by a guard ring 42, which fully encircles the corresponding TSV 28 when viewed from top. In accordance with some embodiments, each guard ring 42 includes a metal ring in each of the metal layers and each of the via layers into which it extends. The metal rings in the plurality of via layers and the plurality of metal layers are interconnected to form a solid metal ring.

In accordance with some embodiments, the topmost ends of the guard ring 42 is in a metal layer that is lower than the top end of the respective TSV 28. For example, when TSVs 28 extend to the bottom of the top metal features 36, guard rings 42 include portions in the metal layer (referred to as M(top-1), not shown separately) immediately under the top metal features 36. In accordance with some embodiments, guard rings 42 include contact plug portions in ILD and at the same level as contact plugs. There may be, or may not be, metal silicide rings lower than and joined to the contact plug portions of the guard rings 42. In accordance with alternative embodiments, guard rings 42 have the bottommost surface higher than the ILD. Guard rings 42 may be electrically grounded, or may be electrically floating.

In accordance with some embodiments, guard rings 44 are also formed in the same processes in which interconnect structure 32 is formed. Guard rings 44 may also include metal rings in the metal layers and via rings between the metal ring, with the metal rings and the via rings interconnected to form solid rings. Metal pads 46 are formed overlying, and are vertically aligned to, the guard rings 44. Guard rings 44 are used to encircle the TSVs that are to be formed by subsequently performed TSV-last processes. Metal pads 46 are used for landing the subsequently formed TSVs, and are used as etch stop layers for the etching of dielectric layers to form TSV openings. As a comparison, in the etching of TSV openings in which TSVs 28 (formed through TSV-first or TSV-middle processes), no etch stop layer is used, while the etching stops inside semiconductor substrate 24.

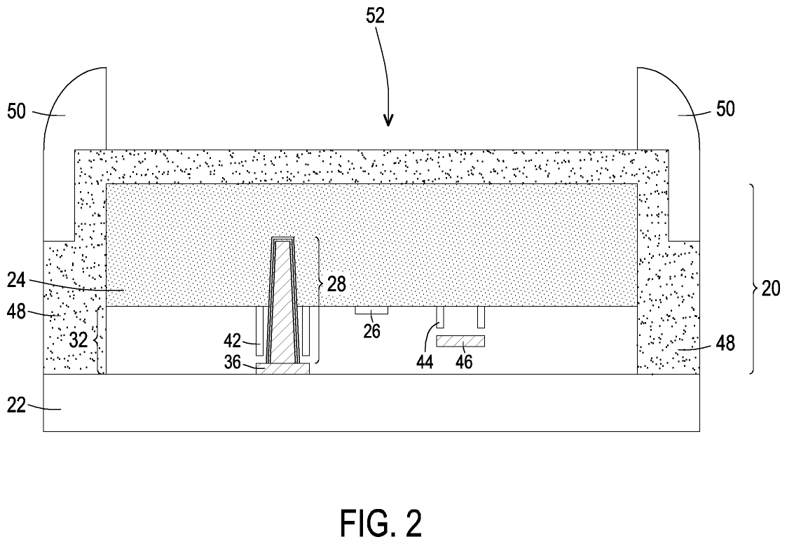

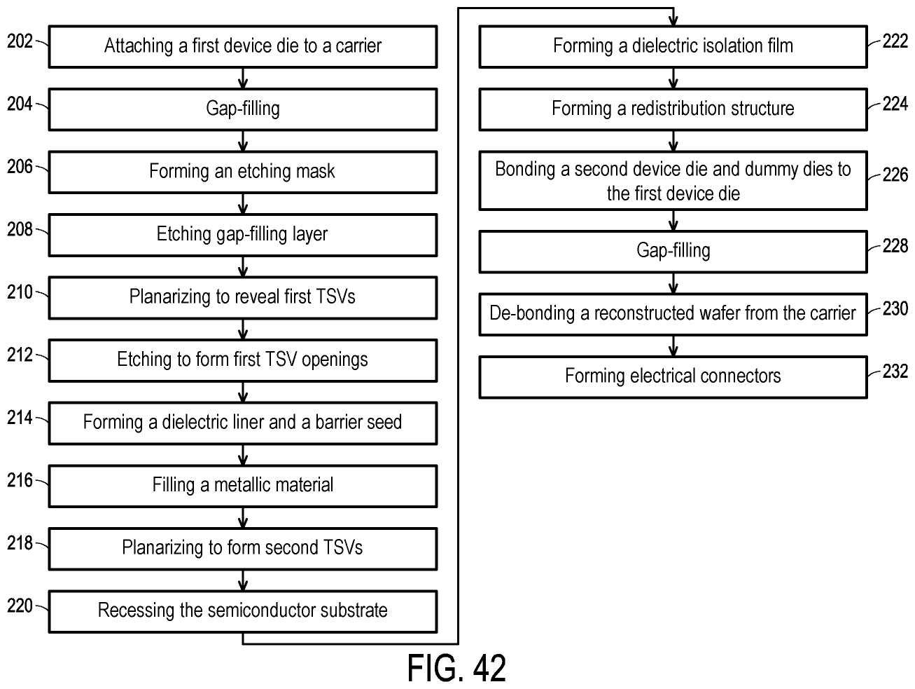

Referring to FIG. 2, device die 20 is attached to carrier 22, with the front side (such as a dielectric bond film (not shown)) of device die 20 facing and attached to carrier 22. The respective process is illustrated as process 202 in the process flow 200 as shown in FIG. 42. It is appreciated that although one device die 20 is illustrated, there are a plurality of device dies 20 attached, and the plurality of device dies 20 may be arranged as an array.

In accordance with some embodiments, carrier 22 includes a bulk semiconductor carrier such as a silicon carrier, and a bond layer on the bulk semiconductor carrier. The bond layer may be formed of a silicon-containing dielectric material selected from SiO, SiC, SiN, SiON, SiOC, SiCN, SiOCN, or the like, or combinations thereof. Device die 20 may be attached to carrier 22 through fusion bonding, with the surface bond layer of device die 20 being bonded to the bond layer in carrier 22 in accordance with some embodiments.

In accordance with alternative embodiments, carrier 22 includes a transparent substrate such as a glass substrate. An adhesive such as a light-to-heat-Conversion (LTHC) material (not shown) is applied on carrier 22, with the LTHC material being configured to be decomposed under the heat of light (such as a laser beam).

Next, as also shown in FIG. 2, a gap-filling process is performed to fill the gaps between neighboring device dies 20, and to encapsulate device dies 20 in a gap-fill layer 48 (also referred to as an encapsulant). The respective process is illustrated as process 204 in the process flow 200 as shown in FIG. 42. In accordance with some embodiments, gap-fill layer 48 comprises a dielectric liner, and a dielectric gap-fill layer over the dielectric liner. The dielectric liner and the dielectric gap-fill layer are not shown separately.

The dielectric liner may be formed of a material that has good adhesion to device dies 20. In accordance with some embodiments, the dielectric liner is formed of or comprises silicon nitride. The dielectric liner may be formed in a conformal deposition process, and hence may be a conformal layer. The dielectric gap-fill layer may be formed of an oxide-base dielectric material such as silicon oxide, silicon oxynitride, a silicate glass, or the like. The dielectric liner and the dielectric gap-fill layer may be formed through deposition processes.

In accordance with alternative embodiments, gap-fill layer 48 is formed of or comprises a molding compound, a molding underfill, or the like. The corresponding process may include dispensing a dielectric material in a flowable form, and curing the dielectric material.

After the gap-filling process, a patterned etching mask 50 is formed. The respective process is illustrated as process 206 in the process flow 200 as shown in FIG. 42. The patterned etching mask 50 may include a patterned photoresist, and may be a single-layer etching mask, a dual-layer etching mask including a bottom anti-reflective coating and a photoresist, or a tri-layer etching mask include a bottom layer, a middle layer, and a top layer. Device die 20 is directly under the opening 52 in etching mask 50.

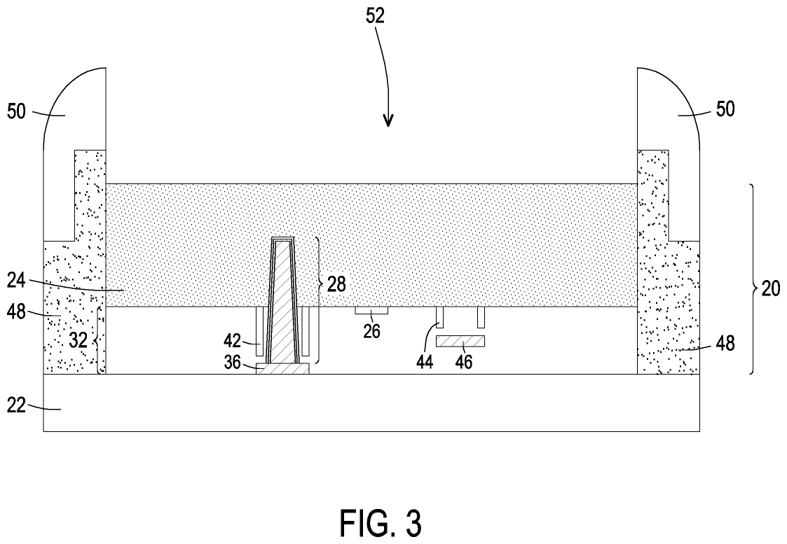

Next, as shown in FIG. 3, the portions of gap-fill layer 48 directly over semiconductor substrate 24 is etched through opening 52, exposing semiconductor substrate 24. The respective process is illustrated as process 208 in the process flow 200 as shown in FIG. 42. Etching mask 50 is then removed, for example, in an ashing process, an etching process, or the like.

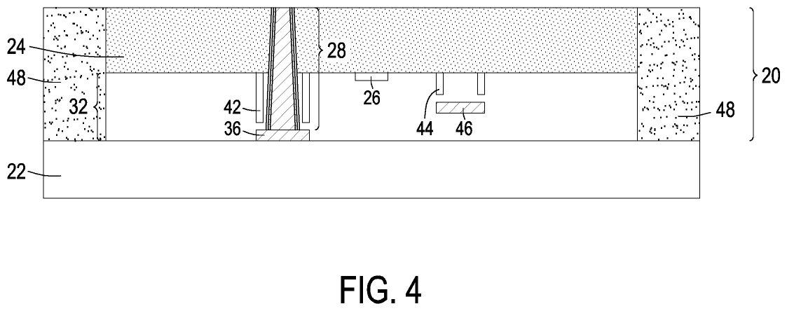

Referring to FIG. 4, a planarization process such as a CMP process or a mechanical polish process is performed to remove excess portions of semiconductor substrate 24 and the gap-fill layer 48. TSVs 28 are thus exposed. The respective process is illustrated as process 210 in the process flow 200 as shown in FIG. 42. The remaining portions of gap-fill layer 48 are referred to as gap-fill regions 48 or encapsulant 48 hereinafter.

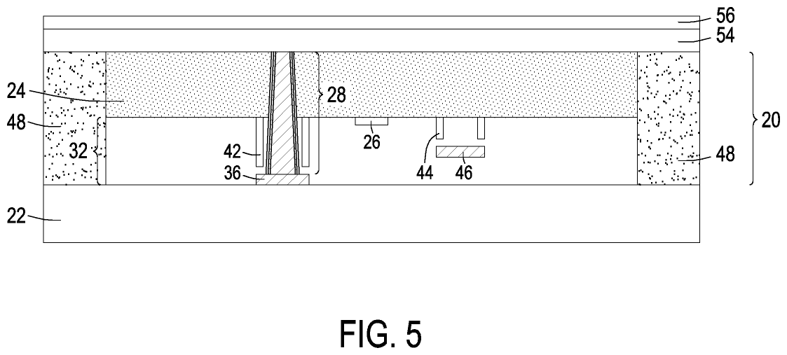

Referring to FIG. 5, pad layer 54 and hard mask 56 are formed through deposition. In accordance with some embodiments, pad layer 54 may be formed of or comprise silicon oxide. The hard mask 56 may be formed of or comprise silicon nitride, boron nitride, or the like, while other applicable materials may be used.

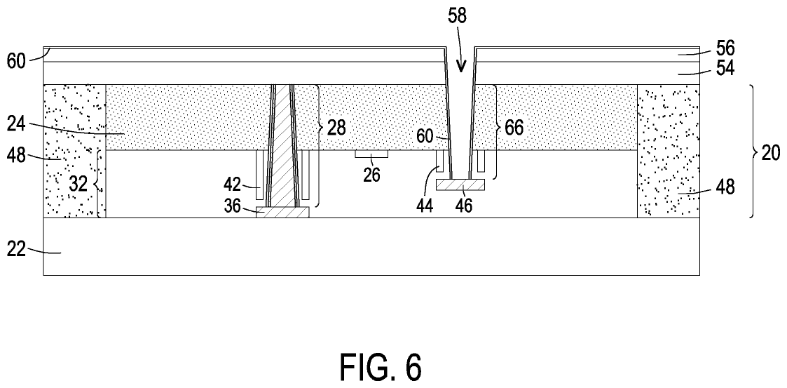

FIGS. 6 through 9 illustrate the formation of TSVs through a TSV-last process in accordance with some embodiments. The process is such named since the formation of the TSVs is after the formation of front-side structures of device die 20. Referring to FIG. 6, an etching process is performed to form TSV opening 58. The respective process is illustrated as process 212 in the process flow 200 as shown in FIG. 42. The etching may be performed using a patterned etching mask (not shown) such as a patterned photoresist, which defines the patterns, locations, and the sizes of a plurality of TSV openings 58.

The etching is performed through an anisotropic etching process, and hard mask 56, pad layer 54, and semiconductor substrate 24 are etched. After the etching process, the patterned etching mask is removed, for example, through ashing, etching, or the like. In the etching process, metal pad 46 acts as the etch stop layer. TSV opening 58 is encircled by, and is spaced apart from, guard ring 44, which was pre-formed, by dielectric materials.

In a subsequent process, dielectric isolation film 60 is formed. The respective process is illustrated as process 214 in the process flow 200 as shown in FIG. 42. The formation process may include a conformal deposition process to deposit dielectric isolation film 60 conformally, and performing an anisotropic etching process to remove the horizontal portions of the dielectric isolation film 60, exposing metal pad 46.

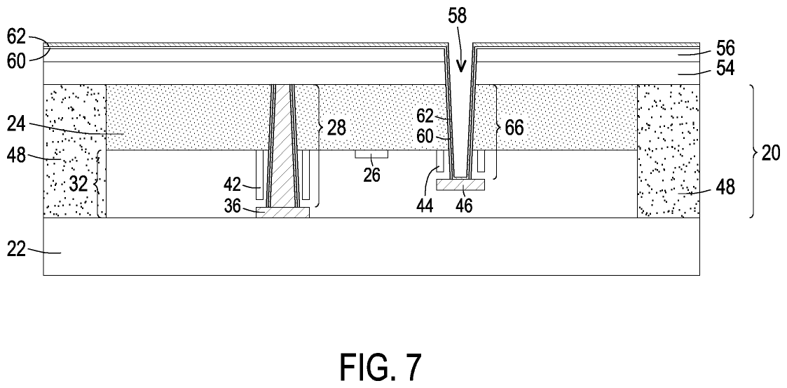

Referring to FIG. 7, barrier seed layer 62 is formed, for example, in a conformal deposition process. The respective process is also illustrated as process 214 in the process flow 200 as shown in FIG. 42. The barrier seed layer 62 may include a conductive barrier layer such as a TiN layer, a TaN layer or the like, and a metal seed layer over the conductive barrier layer. The metal seed layer may comprise copper, and may or may not include a titanium layer. The barrier seed layer 62 may be formed through Physical Vapor Deposition (PVD) in accordance with some embodiments.

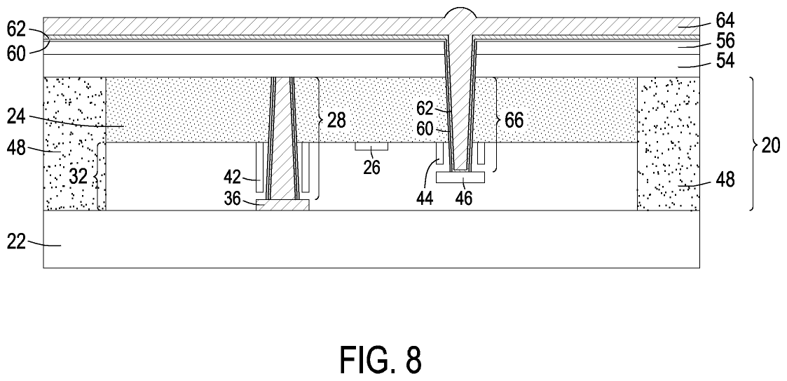

Nest, referring to FIG. 8, a metallic material is deposited to fill the TSV opening, for example, through a plating process. The respective process is illustrated as process 216 in the process flow 200 as shown in FIG. 42. In accordance with some embodiments, the metallic material 64 comprises copper, tungsten, cobalt, or the like.

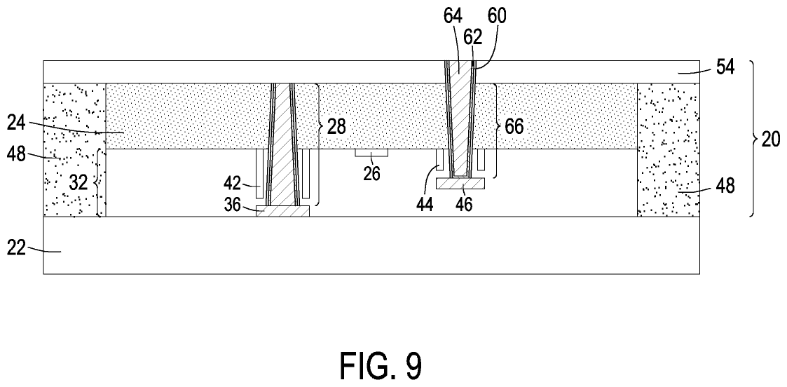

In a subsequent process, a planarization process such as a CMP process or a mechanical process is performed to remove excess portions of the metallic material 64, barrier seed layer 62, and dielectric isolation film 60. Pad layer 54 and hard mask 56 may also be removed by the planarization process, in which semiconductor substrate 24 may be used as a CMP stop layer. The remaining portions of the barrier seed layer 62 and metallic material 64 collectively form TSV 66, which is encircled by dielectric isolation film 60. The resulting structure is shown in FIG. 9. The respective process is illustrated as process 218 in the process flow 200 as shown in FIG. 42.

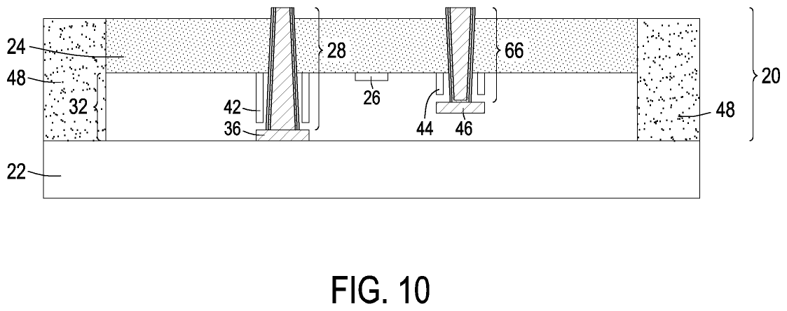

In a subsequent process, as shown in FIG. 10, the semiconductor substrate 24 in device die 20 may be recessed, so that the top portions of TSVs 28 and 66 protrude over semiconductor substrate 24. The respective process is illustrated as process 220 in the process flow 200 as shown in FIG. 42. In the meantime, gap-fill regions 48 may be or may not be recessed. TSV 66 protrudes higher than TSV 28 in accordance with some embodiments.

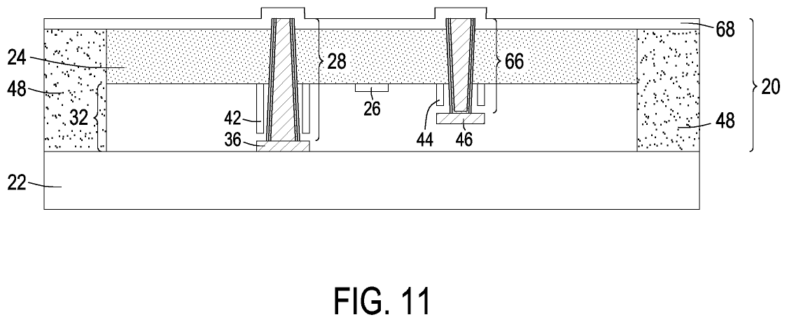

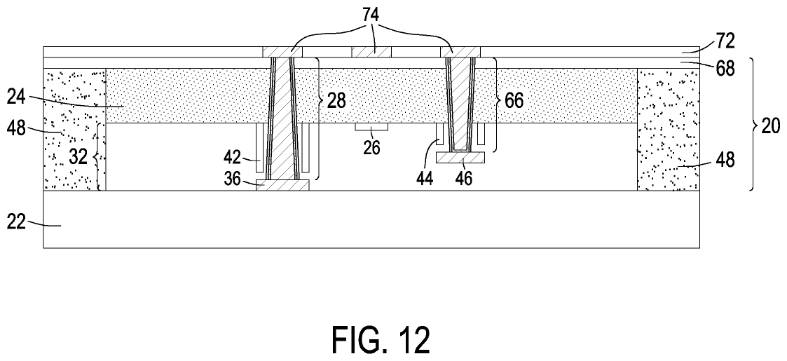

Referring to FIGS. 11 and 12, dielectric isolation film 68 is formed. The respective process is illustrated as process 222 in the process flow 200 as shown in FIG. 42. The formation of dielectric isolation film 68 may include performing a deposition process to deposit a dielectric isolation film 68 into the recess, so that the protruding portions of TSVs 28 and 66 are in the dielectric isolation film 68, as shown in FIG. 11.

Next, as shown FIG. 12, a planarization process is performed. The portions of the dielectric isolation film 68 over TSVs 28 and 66 are removed, and the remaining portions of the dielectric isolation film 68 form the dielectric isolation film 68 as shown in FIG. 12.

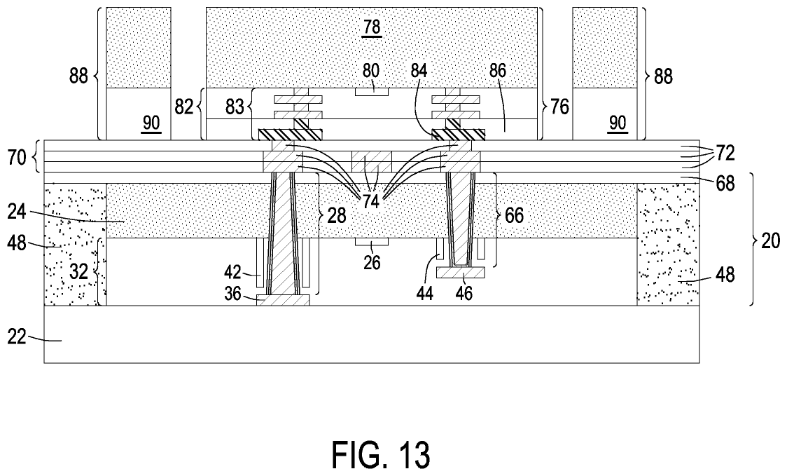

Referring to FIGS. 12 and 13, redistribution structure 70 is formed over and electrically connected to TSVs 28 and 60. The respective process is illustrated as process 224 in the process flow 200 as shown in FIG. 42. In accordance with some embodiments, redistribution structure 70 comprises dielectric layers 72, and conductive features 74 in dielectric layers 72. In accordance with some embodiments, the dielectric layers 72 may include inorganic dielectric material may be selected from SiO, SiC, SiN, SiON, SiOC, SiCN, SiOCN, or the like, or combinations thereof. Alternatively, the dielectric layers 72 may include organic dielectric materials such as polymers, which may include polyimide, polybenzoxazole (PBO), or the like.

For example, as shown in FIG. 12, metal pads 74 are formed as parts of the conductive features 74. Dielectric layer 72 is also formed, with the metal pads 74 being in dielectric layer 72. The formation process may include a damascene process. Next, more dielectric layers 72 and conductive features 74 may be formed, as shown in FIG. 13 for routing. The conductive features 74 may include metal pads, redistribution lines, and the like, and may comprise bond pads as the top features of redistribution structure 70.

Referring to FIG. 13, device dies 76 (also referred to as top dies) are bonded to device dies 20. The respective process is illustrated as process 226 in the process flow 200 as shown in FIG. 42. Although one device die 76 is illustrated, the illustrate device die 76 represents a plurality of device dies 76, each over and bonding to one of the underlying device dies 20. The bonding may be performed through a face-to-back bonding process, with the front side of device die 76 being bonded to the backsides of device die 20. In accordance with some embodiments, each of device dies 76 may be a logic die, which may be a Central Processing Unit (CPU) die, a microcontroller (MCU) die, an input-output (IO) die, a BaseBand die, or the like. Device dies 76 may also include memory dies.

Device dies 76 may include semiconductor substrates 78, which may be silicon substrates. Device dies 76 include integrated circuit devices (such as transistors) 80 and interconnect structures 82 for connecting to the active devices and passive devices in device dies 76. Interconnect structures 82 include metal lines and vias 83, as schematically illustrated.

Each of device dies 76 includes bond pads 84 and bond layer 86 (also referred to as a bond film) at the illustrated bottom surface of the device die 76. The bonding may be achieved through hybrid bonding. For example, bond pads 84 are bonded to conductive features 74 through metal-to-metal direct bonding. In accordance with some embodiments, the metal-to-metal direct bonding comprises copper-to-copper direct bonding. Furthermore, the 86 of device dies 76 are bonded to dielectric layer 72 through fusion bonding, for example, with Si—O—Si bonds being generated.

In accordance with some embodiments, as shown in FIG. 13, a plurality of dummy dies 88 are also attached to the underlying structure. The respective process is also illustrated as process 226 in the process flow 200 as shown in FIG. 42. In accordance with some embodiments, each of dummy dies 88 is attached through layer 90. Layer 90 may be a bond layer including a silicon-containing dielectric material, which may be selected from SiO, SiC, SiN, SiON, SiOC, SiCN, SiOCN, or the like, or combinations thereof. The attachment may be performed by bonding bond layer 90 to dielectric layer 72 through fusion bonding.

In accordance with alternative embodiments, the entire dummy die 88 is formed of a homogeneous material, with no other materials and structures therein. The dummy dies 88 may be formed of a Si, SiC, SiO, SiN, or the like, which may be bonded to dielectric layer 72 directly through fusion bonding.

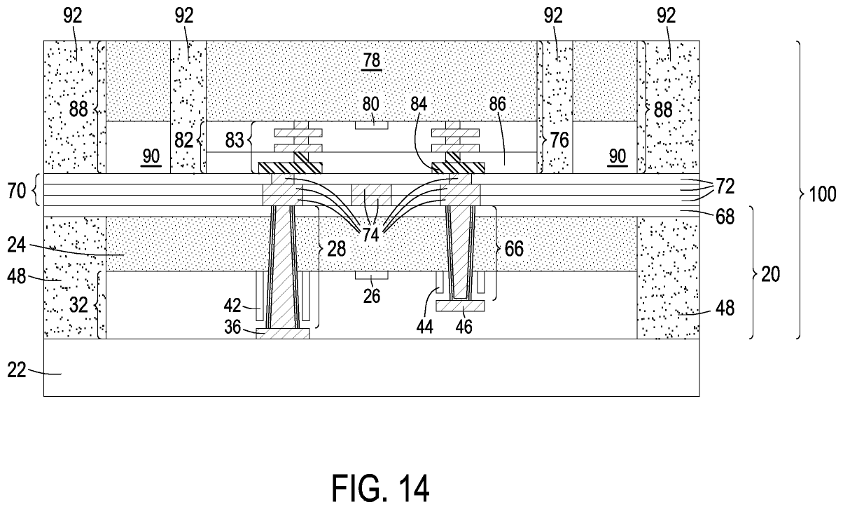

Referring to FIG. 14, gap-fill regions 92 (also referred to as an encapsulant) are formed in a gap-filling process. The respective process is illustrated as process 228 in the process flow 200 as shown in FIG. 42. The formation process, the structure, and the material of gap-fill regions 92 may be selected from the candidate formation processes, the candidate structures, and the candidate materials of gap-fill regions 48. For example, gap-fill regions 92 may include a dielectric liner, and a dielectric gap-fill layer over the dielectric liner. Alternatively, gap-fill regions 92 may comprise a molding compound, a molding underfill, or the like. A planarization process is performed to level the top surfaces of semiconductor substrates 78 of device dies 76, dummy dies 88, and gap-fill regions 92. Throughout the description, the structure over carrier 22 is referred to as reconstructed wafer 100.

The reconstructed wafer 100 is then de-bonded from carrier 22. The respective process is illustrated as process 230 in the process flow 200 as shown in FIG. 42. In accordance with some embodiments in which carrier 22 comprises a silicon wafer, carrier 22 may be removed through a smart cut process, which includes implanting carrier 22, for example, using hydrogen to generate a stress concentrated layer, and annealing the carrier 22, so that carrier 22 may be separated at the stress concentrated layer. The remaining portions of carrier 22 may be removed, for example, through an etching process, a CMP process, or a mechanical grinding process.

In accordance with alternative embodiments in which carrier 22 is a glass carrier. reconstructed wafer 100 may be de-bonded from carrier 22 by projecting a laser beam onto the LTHC coating material, so that the LTHC coating material is decomposed, releasing reconstructed wafer 100 from carrier 22.

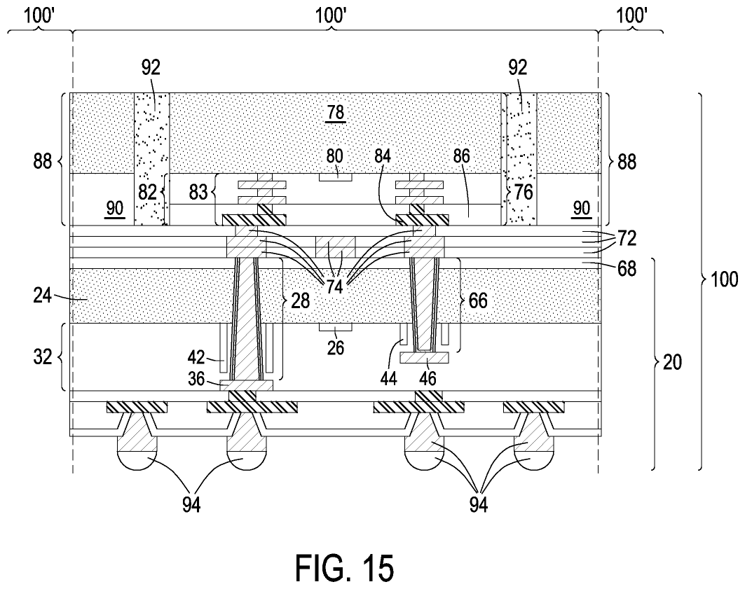

Next, as shown in FIG. 15, electrical connectors 94 are formed. Electrical connectors 94 may comprise solder regions, metal pillars, and/or the like. The respective process is illustrated as process 232 in the process flow 200 as shown in FIG. 42. Reconstructed wafer 100 is thus formed.

In subsequent processes, as also shown in FIG. 15, reconstructed wafer 100 is singulated in a sawing process, so that discrete packages 100′ are formed. The discrete packages 100′ include device dies 20 and 76, and may also include dummy dies 88 in accordance with some embodiments.

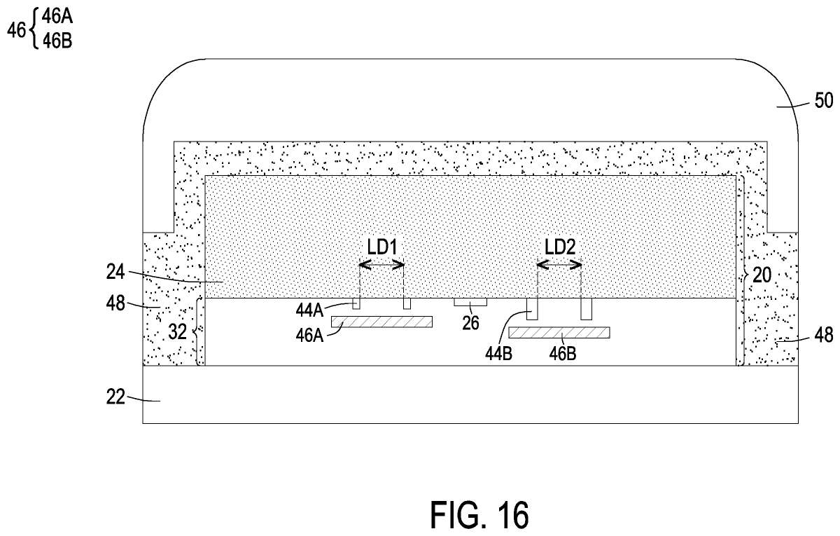

FIGS. 16 through 31 illustrate the cross-sectional views of intermediate stages in the formation of a package in accordance with alternative embodiments of the present disclosure. These processes and structures, instead of including the TSVs formed through TSV-middle (or first) and TSV-last processes, include two TSV last processes to result in TSVs with different sizes and landing positions. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIG. 16, device die 20 is formed and attached to carrier 22. Device die 20 includes semiconductor substrate 24, and may (or may not) include integrated circuit devices 26. Also, guard rings 44 (including guard rings 44A and 44B) and metal pads 46 (including metal pads 46A and 46B) are formed. In accordance with some embodiments, guard rings 44A have a smaller height, and extend into fewer metal layers, than guard rings 44B.

The lateral dimension LD1 (such as a diameter depending on the top view shape) of guard rings 44A may be smaller than the lateral dimension LD2 (such as a diameter depending on the top view shape) of guard rings 44B. For example, the ratio LD2/LD1 may be in the range between about 1 and about 70, and may be in the range between about 5 and about 60, or about 10 and about 50.

Also, metal pads 46A may be at a higher position than metal pads 46B in accordance with some embodiments. For example, metal pads 46A may be immediately under, and may be in contact with the ILD. The metal pads 46B, on the other hand, may be in any metal layer between the ILD and the top metal layer (when device die 20 is viewed upside down), or may be in the top metal layer.

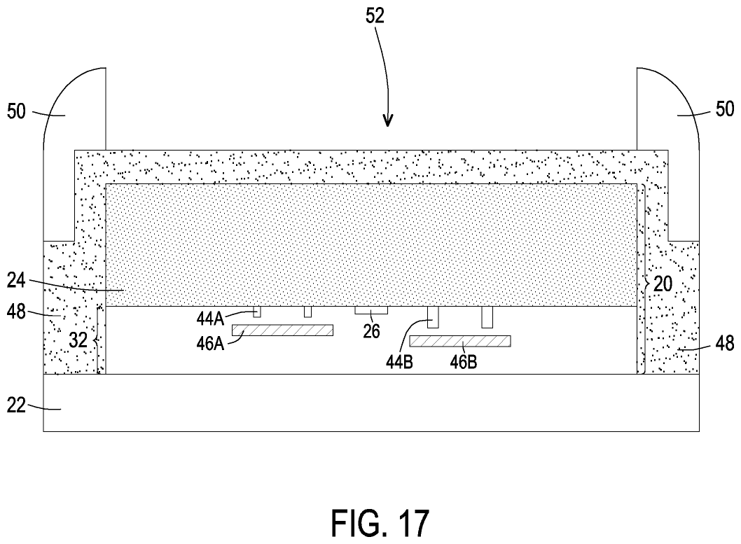

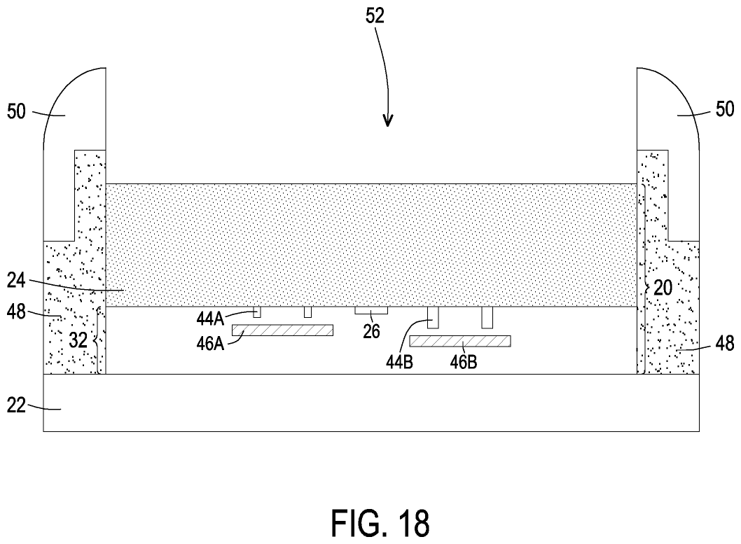

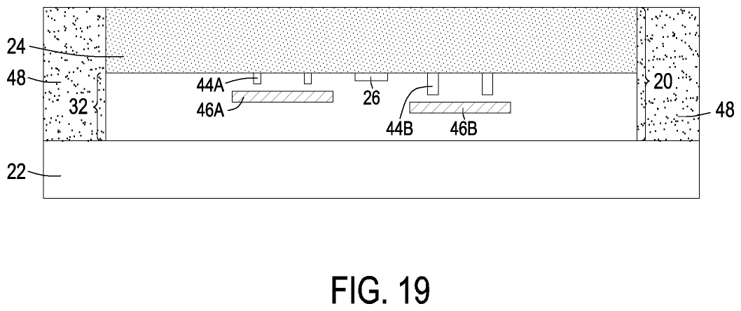

As further shown in FIG. 16, gap-fill layer 48 is formed, followed by the formation of the etching mask 50. The etching mask 50 is then patterned, and opening 52 is formed to overlap device die 20, as shown in FIG. 17. Next, as shown in FIG. 18, the portions of gap-fill layer 48 exposed to opening 52 is removed in an etching process. Etching mask 50 is then removed, followed by a planarization process to reveal semiconductor substrate 24. The resulting structure is shown in FIG. 19.

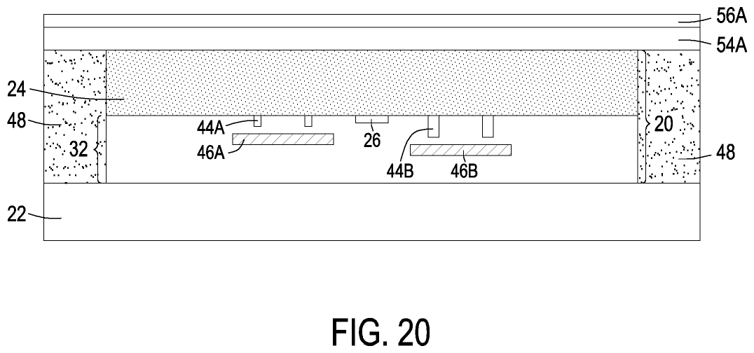

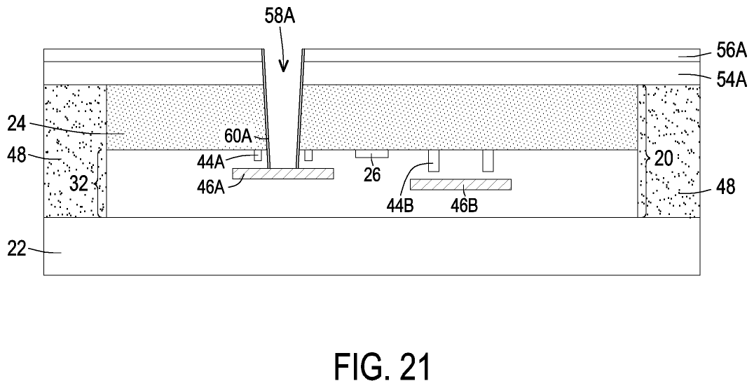

FIGS. 20 through 23 illustrate a first TSV-last process to form TSVs 66A in accordance with some embodiments. Referring to FIG. 20, pad layer 54A and hard mask 56A are formed through deposition processes. The materials and the formation of pad layer 54A and hard mask 56A may be essentially the same as the pad layer 54 and hard mask 56, respectively, in FIG. 7. The pad layer 54A and hard mask 56A and the underlying semiconductor substrate 24 are then etched to form openings 58A, which is encircled by guard ring 44A, as shown in FIG. 21. Metal pad 46A is revealed.

FIG. 21 further illustrates the formation of dielectric isolation film 60A, whose formation involves depositing a dielectric layer and removing the horizontal portions of the dielectric layer through an anisotropic etching process. The bottom portion of the dielectric layer on metal pad 46A is thus removed, exposing metal pad 46A.

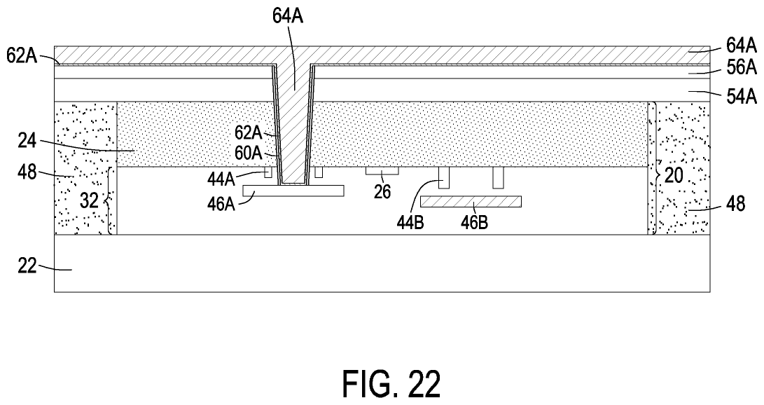

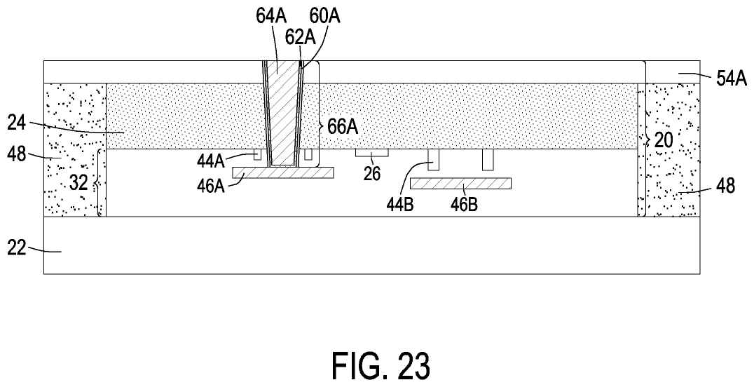

FIG. 22 illustrates the formation of barrier seed layer 62A, and the deposition of conductive material 64A, for example, through plating. The materials and the formation processes of barrier seed layer 62A and conductive material 64A may be essentially the same as that of barrier seed layer 62 and conductive material 64, respectively, as shown in FIG. 8. Next, as shown in FIG. 23, a planarization process is performed to remove excess portions of the dielectric isolation film 60A, barrier seed layer 62A, and conductive material 64A. TSV 66A is thus formed through a first TSV-last process. In the planarization process, pad layer 54A may be used as a CMP stop layer.

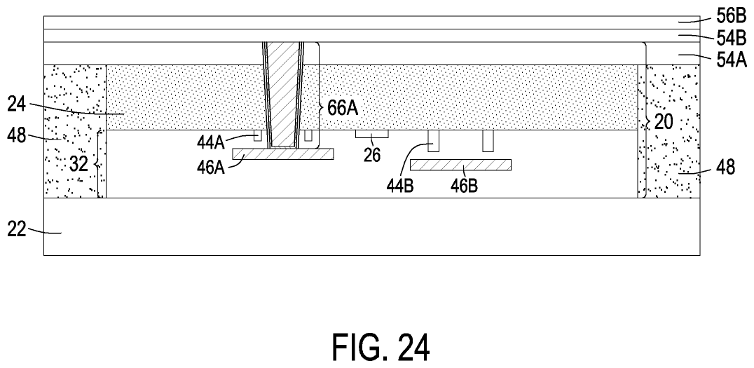

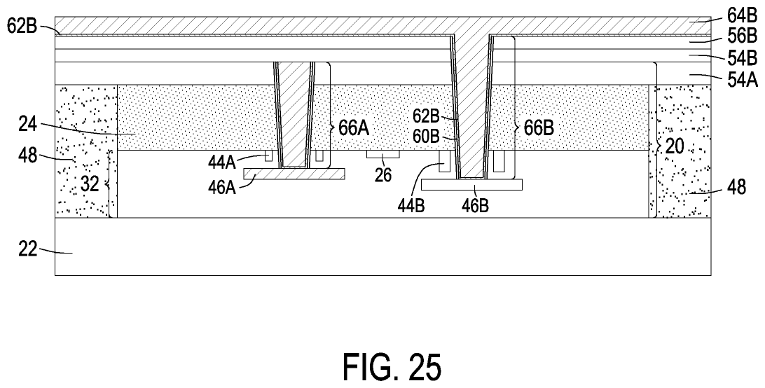

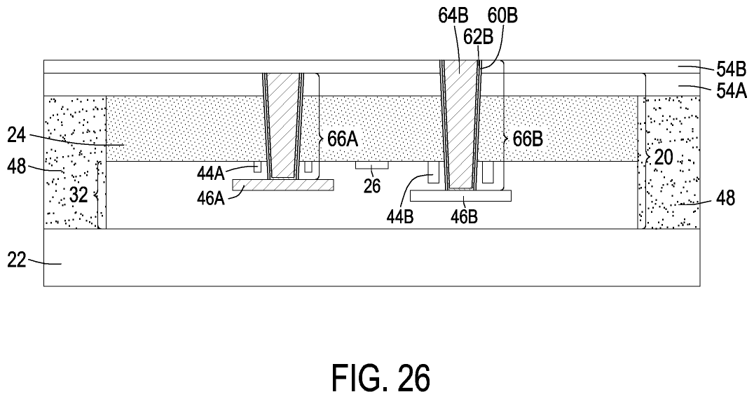

FIGS. 24 through 26 illustrate the formation of TSVs 66B through a second TSV-last process in accordance with some embodiments. The materials and the processes of TSVs 66B may be essentially the same as that of TSVs 66A, and are not repeated herein. FIG. 24 illustrates the formation of pad layer 54B and hard mask 56B. FIG. 25 illustrates the formation of dielectric isolation film 60B, barrier liner layer 62B, and metallic material 64B. FIG. 26 illustrates the planarization process to remove excess portions of the dielectric isolation film 60B, barrier seed layer 62B, and conductive material 64B. TSVs 66B is thus formed through the second TSV-last process.

In above-discussed processes, the openings of TSVs 66A and 66B are formed in separate processes and also filled in separate processes. In accordance with alternative embodiments, the openings of TSVs 66A (which the corresponding openings 58) and 66B (with the corresponding openings not shown) may be formed in separate processes, while filled in common processes. As a result, dielectric liners 60A and 60B may be formed in separate processes or in a common deposition process. Accordingly, dielectric liners 60A and 60B may have the same or different materials, and/or the same or different thicknesses. Barrier seed layers 62A and 62B may have the same or different materials, and/or the same or different thicknesses.

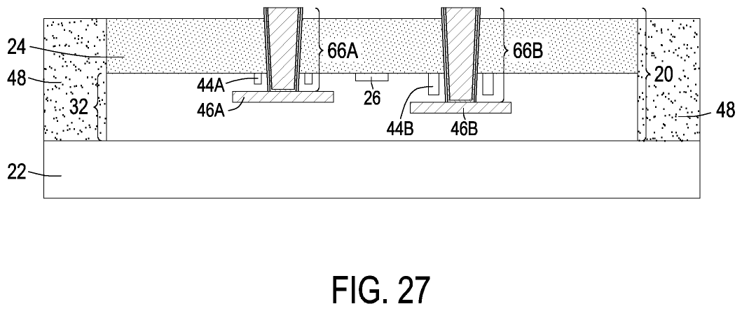

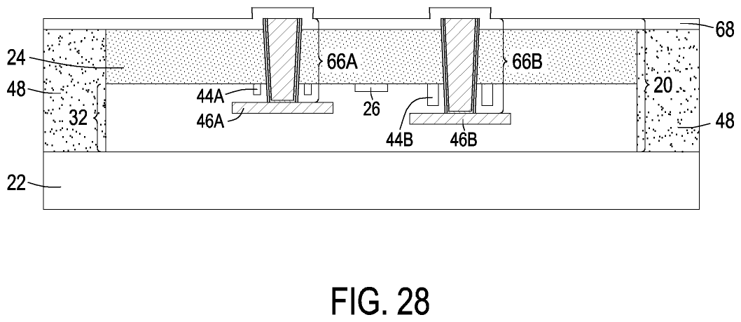

FIGS. 27 through 30 illustrate the formation of the structures over device die 20. FIG. 27 illustrates the recessing of semiconductor substrate 24, so that TSVs 66A and 66B protrude out of the back surface of semiconductor substrate 24. FIG. 28 illustrates the deposition of dielectric isolation film 68, followed by the planarization process to remove excess portions of the dielectric isolation film 68, so that the top surfaces of TSVs 66A and 66B are revealed.

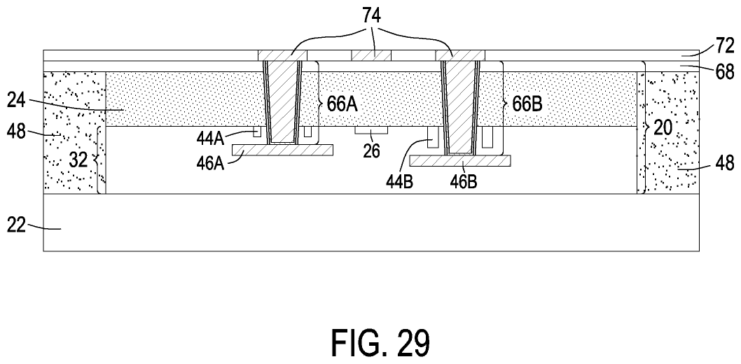

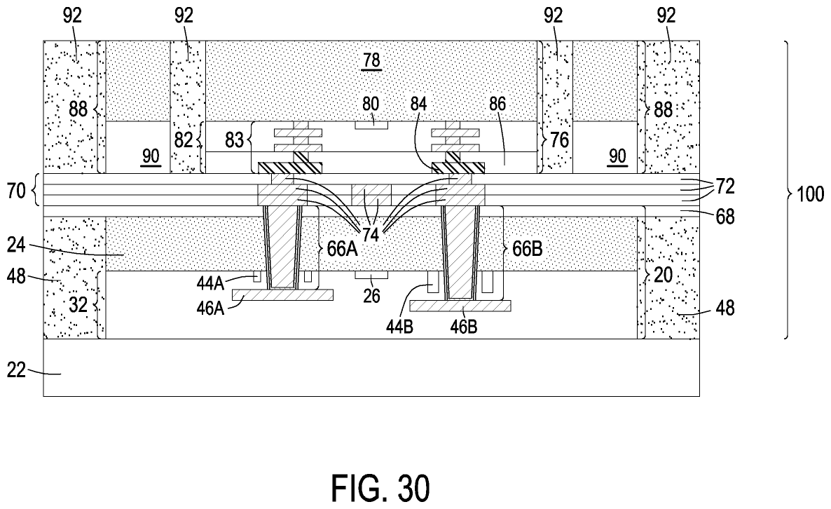

FIGS. 29 and 30 Further illustrate the formation of redistribution structure 70, and the subsequent bonding of device dies 76 and dummy dies 88. Gap-fill regions 92 are then formed as shown in FIG. 30 to form reconstructed wafer 100.

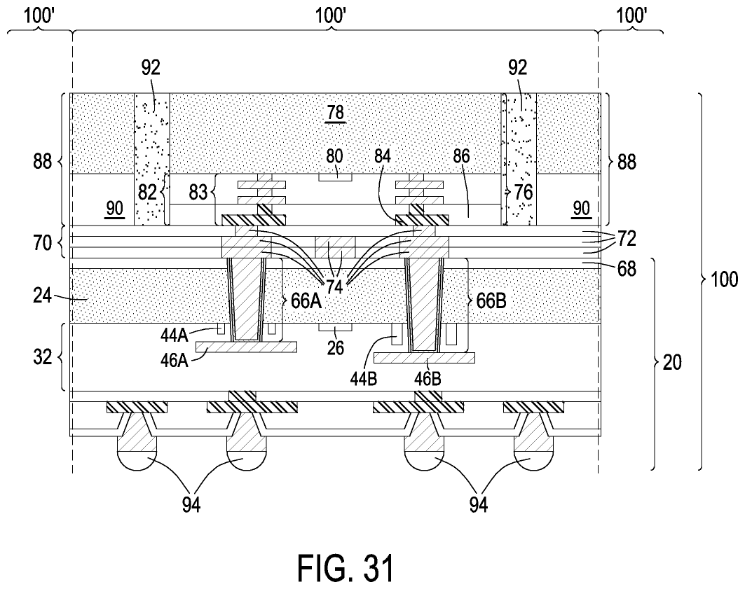

In subsequent processes, reconstructed wafer 100 is de-bonded from carrier 22, followed by the formation of electrical connectors 94, as shown in FIG. 31. The reconstructed wafer 100 is then sawed as packages 100′.

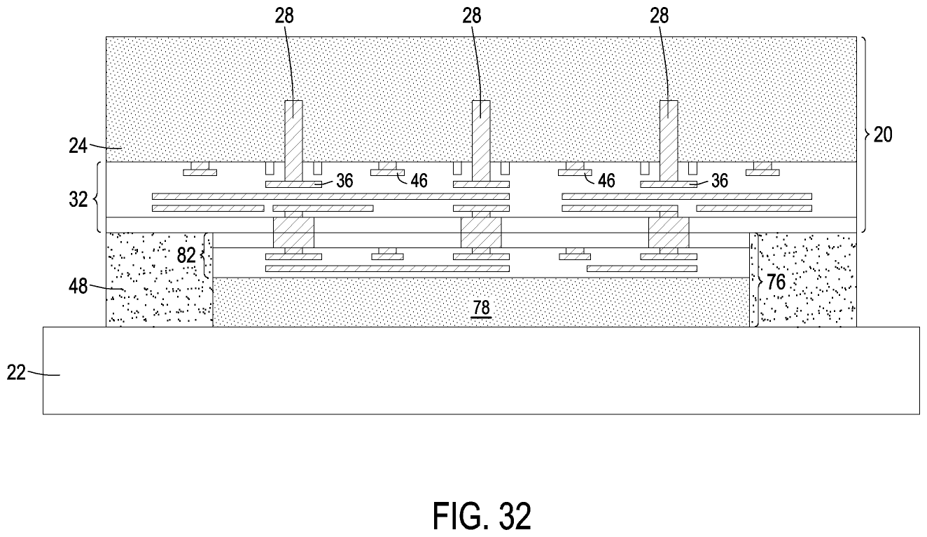

FIGS. 32 through 34 illustrate the cross-sectional views of intermediate stages in the formation of a package in accordance with some embodiments of the present disclosure. These embodiments are essentially the same as the embodiments shown in FIGS. 1 through 15 (which includes a TSV-middle (or first) process and a TSV-last process), except that face-to-face bonding, rather than face-to-back bonding, is performed. The details thus may be found from the discussion of the embodiments shown in FIGS. 1 through 15.

Referring to FIG. 32, device die 20 is bonded with device die 76 through face-to-face bonding process. TSVs 28 are formed through a TSV-first process, for example, having TSVs 28 contacting the metal pads in the metal layer (M0 or M1) that is closest to semiconductor substrate 24. Gap-filling regions 48 are formed to encapsulate device die 76. The structure including device dies 20 and 76 is then attached to carrier 22.

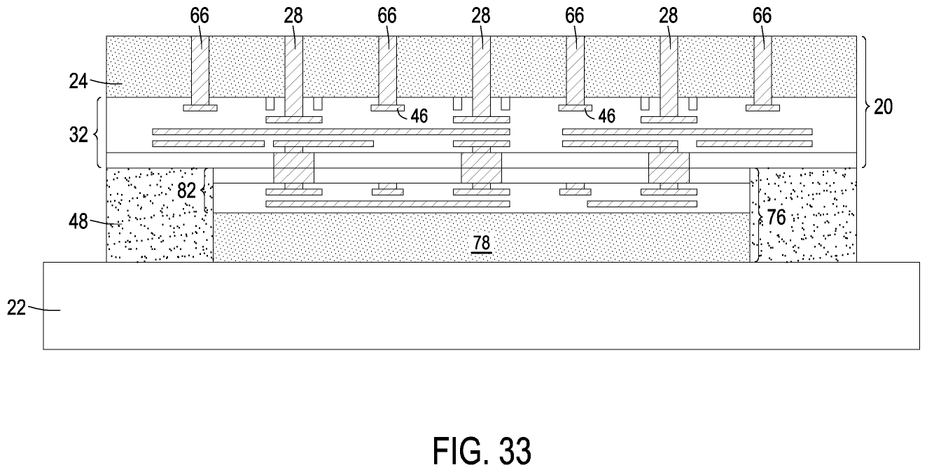

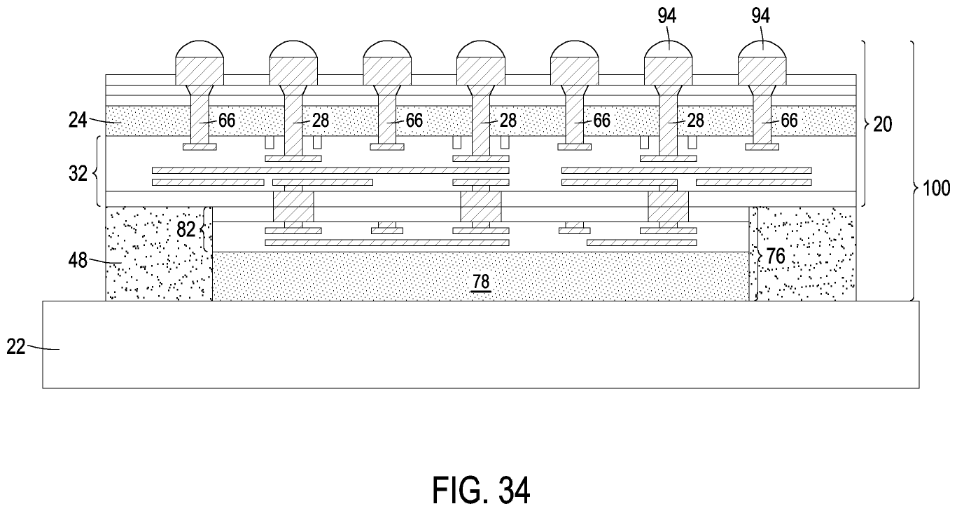

Referring to FIG. 33, the semiconductor substrate 24 is thinned, followed by the formation of TSVs 66 through a TSV-last process. The details of the formation process may be found referring to FIGS. 5 through 9. FIG. 34 illustrates the formation of electrical connectors 94 in accordance with some embodiments. Reconstructed wafer 100 is thus formed. In subsequent processes, the reconstructed wafer 100 is de-bonded from carrier 22, and may be sawed into packages.

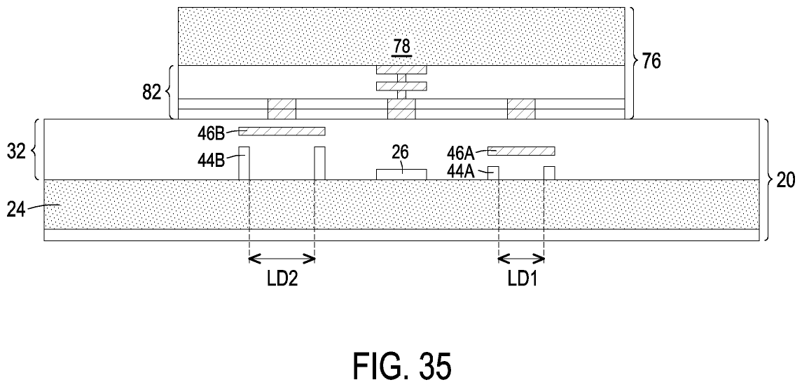

FIGS. 35 through 37 illustrate the cross-sectional views of intermediate stages in the formation of a package in accordance with alternative embodiments of the present disclosure. These embodiments are essentially the same as the embodiments shown in FIGS. 16 through 31 (which includes two TSV-last processes), except that face-to-face bonding, rather than face-to-back bonding, is performed. The details thus may be found from the discussion of the embodiments shown in FIGS. 16 through 31.

Referring to FIG. 35, device die 20 is formed. Device die 20 includes metal pads 46A and 46B in different metal layers, and guard rings 44A and 44B having different lateral dimensions LD1 and LD2. Device die 76 is bonded to device die 20 through face-to-face bonding, for example, with bond pads bonding to each other, and dielectric bond layers bonding to each other.

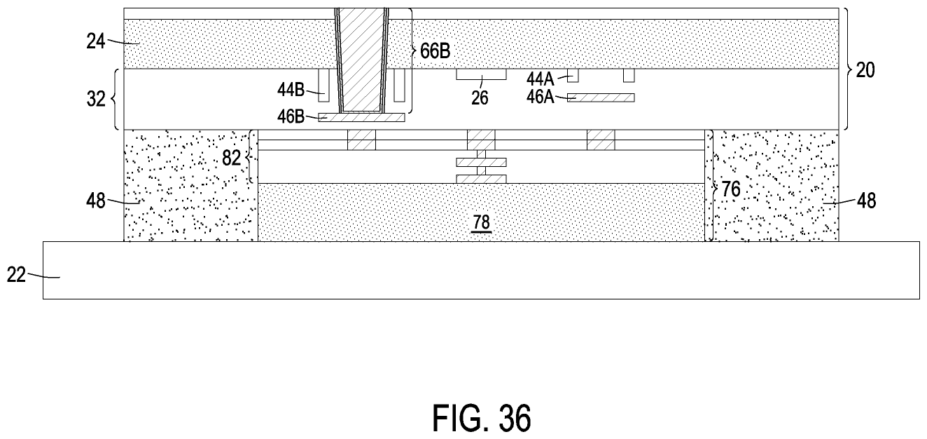

Referring to FIG. 36, gap-filling regions 48 are formed to encapsulate device die 76, and the resulting structure is attached to carrier 22. TSVs 66B are formed through a first TSV-last process, with TSVs 66B landing on the metal pads 46B in a top metal layer (When device die is viewed upside down as shown in FIG. 35) that is farthest from semiconductor substrate 24 than other metal layers. The structure including device dies 20 and 76 are then attached to carrier 22.

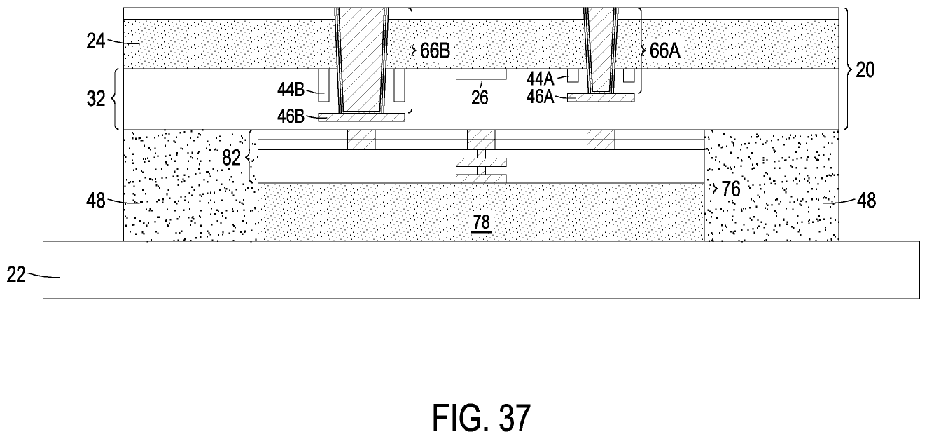

FIG. 37 illustrates the formation of TSVs 66A through a second TSV-last process. TSVs 66A may land on the metal pads 46A in a metal layer (M0 or M1) that is closest to semiconductor substrate 24. The details of the formation process may be found referring to FIGS. 20 through 26. Subsequently, the processes as shown in FIGS. 27-31 may be performed to finish the formation of the reconstructed wafer 100 and the sawing process.

In above discussed processes, two or more TSV formation processes may be performed, each selected from a TSV-first process, a TSV-middle process, and a TSV-last process. Separating the formation of TSVs into different formation processes may advantageously result in the TSVs to have different lateral dimensions, and/or landing on the metal pads that are in different metal layers, without adversely increasing their lateral dimension unnecessarily. This may suit to the customized needs of the circuits. For example, the power TSVs used for conducting power may need to have greater lateral dimensions to conduct high currents. The power TSVs thus may occupy large chip areas. Signal TSVs, on the other hand, may be formed narrower without sacrificing their function of conducting signals. Also, there may be more signal TSVs needed than power TSVs.

In accordance with the embodiments of the present disclosure, by forming TSVs through two or more formation processes, TSVs may be formed with greatest aspect ratios (the ratio of heights to widths) allowed by the respective formation processes, yet still have two or more different kinds of widths to satisfy the circuit requirement with the smallest chip area usage. For example, the TSVs 28 in FIGS. 15 and 34 and the TSVs 66B in FIGS. 31 and 37 may be used for forming power TSVs, and may be taller and wider. The TSVs 66 in FIGS. 15 and 34 and the TSVs 66A in FIGS. 31 and 37 may be used for forming signal TSVs, and may be shorter and narrower.

In accordance with some embodiments, the TSVs formed using different processes, when having different heights and different lateral dimensions, may still have the same aspect ratios, which are the greatest aspect ratios allowed by the forming technologies.

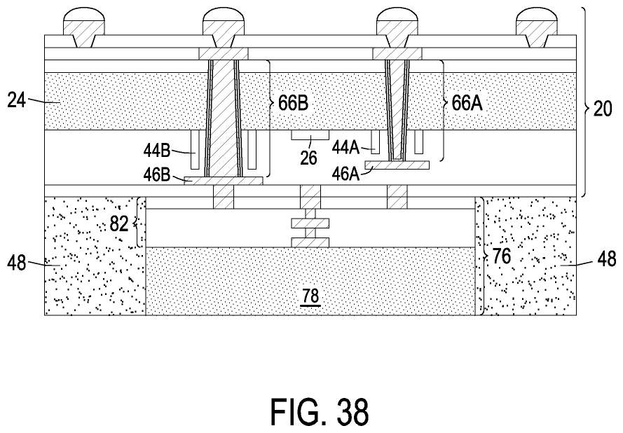

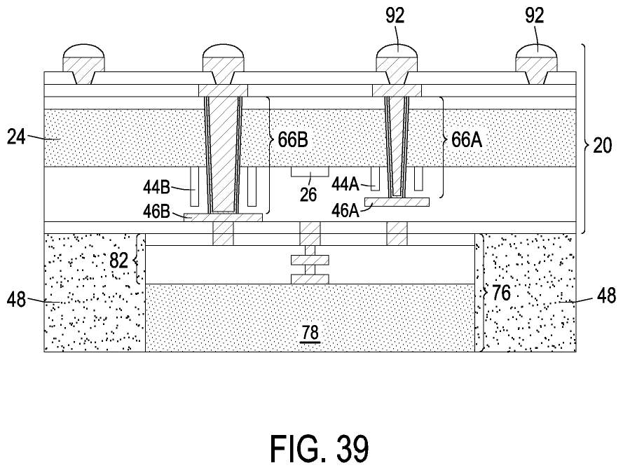

FIG. 38 illustrates a package formed through face-to-face bonding, and includes the TSVs 28 formed through a TSV-middle process and TSVs 66 formed through a TSV-last process in accordance with some embodiments. FIG. 39 illustrates a package formed through face-to-face bonding, and includes the TSVs 66A and TSVs 66B formed through two TSV-last processes in accordance with some embodiments.

It is appreciated that whether the TSVs are formed through TSV first, TSV middle, or TSV-last process may be found and determined from the structures. For example, when the TSV-first or the TSV-middle processes are used, the portions of the TSVs closer to the front side of the semiconductor substrate are wider than the portions of the TSVs closer to the backside of the semiconductor substrate, which is opposite to the TSVs formed through TSV-last processes. Also, whether TSV-first process or TSV-middle process is used may be determined from the positions of the metal pads on which the TSVs land. For example, when the metal pads are closer to the semiconductor substrate, it may be determined that TSV-first process is used, and when the metal pads are far away from the semiconductor substrate, it may be determined that TSV-last process is used.

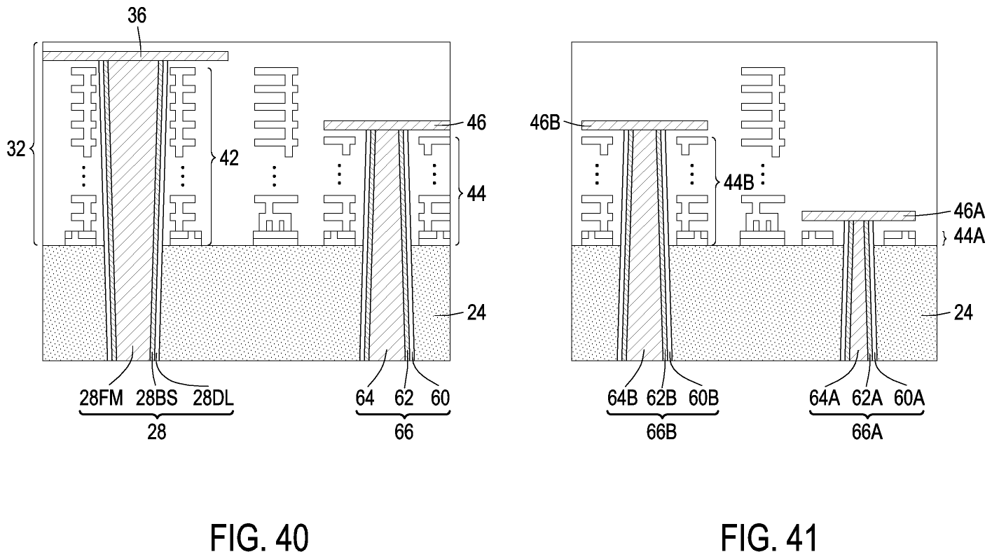

FIGS. 40 and 41 illustrate some details of TSVs, the guard rings, and metal pads, and the corresponding metal layers in accordance with some embodiments. TSV 28 includes dielectric liner 28DL, barrier seed layer 28BS, and filling metal 28FM. The corresponding layers of TSVs 66, 66A, and 66B are also illustrated and marked.

It is appreciated that although the TSVs formed using TSV-first process or TSV-middle process, the TSVs formed using a first TSV-last process, and the TSVs formed using a second TSV-last process are shown by different embodiments, these TSVs may be formed in the same device die in any combination to suit to the different circuit requirements.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By separating the formation of TSVs having different functions to different TSV formation processes, the resulting TSVs may have greatest aspect ratios, thus having the advantageous feature of occupying smallest possible chip areas, while the different needs requested by circuits may still be satisfied.

In accordance with some embodiments of the present disclosure, a method comprises forming a first device die comprising forming an integrated circuit on a semiconductor substrate; and forming an interconnect structure on the semiconductor substrate, wherein the interconnect structure comprises a plurality of metal layers; bonding a second device die to the first device die; forming gap-fill regions surrounding the second device die; in a first formation process, forming a first TSV penetrating through the semiconductor substrate, wherein the first TSV has a first width; and in a second formation process, forming a second TSV penetrating through the semiconductor substrate, wherein the second TSV has a second width different from the first width. In an embodiment, the first TSV and the second TSV are formed as having different heights and a same aspect ratio.

In an embodiment, both of the first TSV and the second TSV are formed using TSV-last process processes. In an embodiment, the forming the first TSV comprises a first etching process to etch the semiconductor substrate and to form a first opening penetrating through the semiconductor substrate; and the forming the second TSV comprises a second etching process to etch the semiconductor substrate and to form a second opening penetrating through the semiconductor substrate, wherein the first opening and the second opening are formed in separate etching processes. In an embodiment, the first TSV is formed before the second device die is bonded to the first device die, and the second TSV is formed after the second device die is bonded to the first device die, and the second TSV extends from a backside of the semiconductor substrate into the semiconductor substrate.

In an embodiment, the method further comprises, before the second device die is bonded to the first device die, forming a first guard ring encircling the first TSV; and forming a second guard ring encircling a space filled with dielectric materials, wherein the second TSV is formed to insert into the space encircled by the second guard ring. In an embodiment, the first TSV is formed using a TSV-middle process, and the second TSV is formed using a TSV-last process.

In an embodiment, the first TSV is formed using a TSV-first process, and the second TSV is formed using a TSV-last process. In an embodiment, the second device die is bonded to the first device die through face-to-back bonding, with a front side of the second device die facing a backside of the first device die. In an embodiment, the second device die is bonded to the first device die through face-to-face bonding, with a front side of the second device die facing a front side of the first device die.

In accordance with some embodiments of the present disclosure, a structure comprises a first device die comprising a semiconductor substrate; integrated circuit devices on the semiconductor substrate; an interconnect structure on the integrated circuit devices, wherein the interconnect structure comprises a plurality of metal layers; and a first TSV and a second TSV, wherein the first TSV and the second TSV land on different metal layers of the plurality of metal layers; and a second device die joined to the first device die, wherein the first TSV and the second TSV are electrically connected to the second device die. In an embodiment, the first TSV has a first wider end and a first narrower end narrower than the first wider end, wherein the first wider end is on a front side of the semiconductor substrate; and the second TSV has a second wider end and a second narrower end narrower than the second wider end, and wherein the second wider end is on a backside of the semiconductor substrate.

In an embodiment, the first TSV has a first wider end and a first narrower end narrower than the first wider end; and the second TSV has a second wider end and a second narrower end narrower than the second wider end, wherein both of the first wider end and the second wider end are on a backside of the semiconductor substrate. In an embodiment, the first TSV has a first wider end and a first narrower end narrower than the first wider end; and the second TSV has a second wider end and a second narrower end narrower than the second wider end, wherein the first narrower end and the second narrower end are at different levels of the first device die. In an embodiment, the first TSV and the second TSV have different heights.

In accordance with some embodiments of the present disclosure, a structure comprises a first device die comprising a semiconductor substrate; integrated circuit devices on the semiconductor substrate; an interconnect structure on the integrated circuit devices, wherein the interconnect structure comprises a plurality of metal layers; a first TSV penetrating through the semiconductor substrate, wherein the first TSV has a first wider end and a first narrower end narrower than the first wider end, and wherein the first wider end is on a front side of the semiconductor substrate; and a second TSV having a second wider end and a second narrower end narrower than the second wider end, wherein the second wider end is on a backside of the semiconductor substrate.

In an embodiment, the structure further comprises a second device die bonding to the first device die, wherein the second device die is on the backside of the semiconductor substrate. In an embodiment, the structure further comprises a first metal pad contacting the first TSV; and a second metal pad contacting the second TSV, wherein the first metal pad and the second metal pad are in different metal layers of the interconnect structure. In an embodiment, the first TSV is encircled by a first dielectric liner, and the second TSV is encircled by a second dielectric liner, and the first dielectric liner and the second dielectric liner are formed of different materials. In an embodiment, the first TSV comprises a first barrier layer, and the second TSV comprises a second barrier layer, and the first barrier layer and the second barrier layer comprise different materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first device die comprising:
forming an integrated circuit on a semiconductor substrate; and
forming an interconnect structure on the semiconductor substrate, wherein the interconnect structure comprises a plurality of metal layers;
bonding a second device die to the first device die;
forming gap-fill regions surrounding the second device die;
in a first formation process, forming a first through-silicon via (TSV) penetrating through the semiconductor substrate, wherein the first TSV has a first width; and
in a second formation process, forming a second TSV penetrating through the semiconductor substrate, wherein the second TSV has a second width different from the first width.

2. The method of claim 1, wherein the first TSV and the second TSV are formed as having different heights and a same aspect ratio.

3. The method of claim 1, wherein both of the first TSV and the second TSV are formed using TSV-last process processes.

4. The method of claim 3, wherein:
the forming the first TSV comprises a first etching process to etch the semiconductor substrate and to form a first opening penetrating through the semiconductor substrate; and
the forming the second TSV comprises a second etching process to etch the semiconductor substrate and to form a second opening penetrating through the semiconductor substrate, wherein the first opening and the second opening are formed in separate etching processes.

5. The method of claim 1, wherein the first TSV is formed before the second device die is bonded to the first device die, and the second TSV is formed after the second device die is bonded to the first device die, and the second TSV extends from a backside of the semiconductor substrate into the semiconductor substrate.

6. The method of claim 5 further comprising:
before the second device die is bonded to the first device die, forming a first guard ring encircling the first TSV; and
forming a second guard ring encircling a space filled with dielectric materials, wherein the second TSV is formed to insert into the space encircled by the second guard ring.

7. The method of claim 5, wherein the first TSV is formed using a TSV-middle process, and the second TSV is formed using a TSV-last process.

8. The method of claim 5, wherein the first TSV is formed using a TSV-first process, and the second TSV is formed using a TSV-last process.

9. The method of claim 1, wherein the second device die is bonded to the first device die through face-to-back bonding, with a front side of the second device die facing a backside of the first device die.

10. The method of claim 1, wherein the second device die is bonded to the first device die through face-to-face bonding, with a front side of the second device die facing a front side of the first device die.

11. A structure comprising:
a first device die comprising:
a semiconductor substrate;
integrated circuit devices on the semiconductor substrate;
an interconnect structure on the integrated circuit devices, wherein the interconnect structure comprises a plurality of metal layers; and
a first through-silicon via (TSV) and a second TSV, wherein the first TSV and the second TSV land on different metal layers of the plurality of metal layers; and
a second device die joined to the first device die, wherein the first TSV and the second TSV are electrically connected to the second device die.

12. The structure of claim 11, wherein:
the first TSV has a first wider end and a first narrower end narrower than the first wider end, wherein the first wider end is on a front side of the semiconductor substrate; and
the second TSV has a second wider end and a second narrower end narrower than the second wider end, and wherein the second wider end is on a backside of the semiconductor substrate.

13. The structure of claim 11, wherein:
the first TSV has a first wider end and a first narrower end narrower than the first wider end; and
the second TSV has a second wider end and a second narrower end narrower than the second wider end, wherein both of the first wider end and the second wider end are on a backside of the semiconductor substrate.

14. The structure of claim 11, wherein:
the first TSV has a first wider end and a first narrower end narrower than the first wider end; and
the second TSV has a second wider end and a second narrower end narrower than the second wider end, wherein the first narrower end and the second narrower end are at different levels of the first device die.

15. The structure of claim 11, wherein the first TSV and the second TSV have different heights.

16. A structure comprising:
a first device die comprising:
a semiconductor substrate;
integrated circuit devices on the semiconductor substrate;
an interconnect structure on the integrated circuit devices, wherein the interconnect structure comprises a plurality of metal layers;
a first through-silicon via (TSV) penetrating through the semiconductor substrate, wherein the first TSV has a first wider end and a first narrower end narrower than the first wider end, and wherein the first wider end is on a front side of the semiconductor substrate; and
a second TSV having a second wider end and a second narrower end narrower than the second wider end, wherein the second wider end is on a backside of the semiconductor substrate.

17. The structure of claim 16 further comprising a second device die bonding to the first device die, wherein the second device die is on the backside of the semiconductor substrate.

18. The structure of claim 16 further comprising:
a first metal pad contacting the first TSV; and
a second metal pad contacting the second TSV, wherein the first metal pad and the second metal pad are in different metal layers of the interconnect structure.

19. The structure of claim 16, wherein the first TSV is encircled by a first dielectric liner, and the second TSV is encircled by a second dielectric liner, and the first dielectric liner and the second dielectric liner are formed of different materials.

20. The structure of claim 16, wherein the first TSV comprises a first barrier layer, and the second TSV comprises a second barrier layer, and the first barrier layer and the second barrier layer comprise different materials.
